(19) United States
(12) Patent Application Publication
(10) Pub. No.: US 2006/0254638 A1
(43) Pub. Date: Nov. 16, 2006

(54) Small electrical appliance driven by a thermoelectric generator

(76) Inventors: Ran Carmeli, Rinatya (IL); Jonathan Einav, Raanana (IL); Itai Yonat, Tel Aviv (IL)

Correspondence Address: HENRY M FEIEREISEN, LLC, 350 FIFTH AVENUE, SUITE 4714, NEW YORK, NY, 10118, US

(21) Appl. No.: 11/190,309

(22) Filed: Jul. 26, 2005

(30) Foreign Application Priority Data
May 11, 2005 (IL) 168 567

(51) Int. Cl. H01L 35/30

(52) U.S. Cl. 136/205

(57) ABSTRACT

A small electrical appliance, such as an electrical wet shaver or electrical toothbrush, is driven by the energy generated by the temperature differential in its environment of use. The heat of the hot water used when wet shaving with an electrical wet shaver, versus the relatively lower temperature of the handle, which is in an environment at room temperature, causes a thermoelectric generator operating as a Peltier cooler using the Seebeck mode, to generate enough electrical power to drive the motor of the appliance and/or to recharge a rechargeable electrical battery, which may also be present.

### CROSS-REFERENCES TO RELATED APPLICATIONS

This application claims the priority of Israeli Patent Application, Serial No. 168567, filed May 11, 2005, pursuant to 35 U.S.C. 119(a)-(d), the subject matter of which is/are incorporated herein by reference.

### FIELD OF THE INVENTION

The present invention is in the field of small electrical appliances, such as electrical wet shavers or electrical toothbrushes. In particular, the invention allows recovering of wasted heat energy, e.g., that carried by hot water, to perform a useful task such as to provide needed power to operate a small appliance. The energy to operate the appliance is preferably derived from the same hot water that is used to wash the appliance during use, which is generally washed under hot water.

### BACKGROUND OF THE INVENTION

Electrical shavers are usually operated and powered by batteries, which may be conventional or rechargeable batteries. The same holds true for electric toothbrushes.

Recently, wet electrical shavers were introduced into the market, where the shaving quality is improved by combining the benefits of both techniques, wet shaving together with electrical shaving.

In the field of wet electrical shavers, the traditional power source is a battery confined in a waterproof compartment, which is included in the wet electrical shaver, usually in its handle. This battery, either of the conventional or rechargeable type, needs to be replaced and/or recharged from time to time.

Thus, in the case of conventional type batteries, such a wet electrical shaver includes a chemical power source. These batteries, when exhausted, require treatment in a special manner to prevent environmental damage. However, if the exhausted batteries are not treated correctly, damage to the environment and even to the user may be caused.

If the shaver includes rechargeable batteries, a charger is required. Such a charger is relatively complicated, since it needs to be constructed to be used in a highly humid environment, such as bathrooms.

A typical prior art electrical wet shaver, such as that manufactured by GILLETTE, includes a battery in a special waterproof compartment enclosed in the shaver handle. The manufacturer recommends replacing the battery from time to time to achieve optimal shaving.

Electrical toothbrushes are also powered in most cases by rechargeable batteries. Thus, a charger is required together with the electrical toothbrush, leading to the same drawbacks described above.

A Peltier cooler is best known as a thermoelectric cooler that generates a temperature difference between two opposing surfaces when a voltage is applied across the device. It is known that a Peltier cooler can be operated in the Seebeck mode as an electrical generator. That is, when a temperature differential is applied across the two opposing surfaces of the thermoelectric generator, it generates a DC voltage responsive to the temperature differential. This effect is described in a comprehensive way by Gao Min and D. M. Rowe in “Optimization of thermoelectric module geometry for ‘waste heat’ electric power generation,” Journal of Power Sources, Vol. 38 pp. 253-259 (1992). As discussed in this publication, an optimized Peltier cooler operated in Seebeck effect can provide power of the order of several hundreds of milliwatts (several 100 mW) when a temperature difference of 50 degrees Celsius is applied to the opposing surfaces of the thermoelectric unit.

One known use of the Peltier effect is an apparatus for generating power in order to operate an electrical fan to increase cooling efficiency of electrical items, as described e.g. in U.S. Pat. No. 5,419,780.

### SUMMARY OF THE INVENTION

In one aspect, the present invention relates to an apparatus that converts the temperature difference present in the operating environment of a small appliance, such as a wet electric shaver or an electric toothbrush, into operating power therefor.

In accordance with the invention, the apparatus includes a thermoelectric generator that converts the energy derived from a temperature differential into electrical energy through a Peltier cooler operating in Seebeck effect.

The thermoelectric generator is positioned inside the handle of the appliance, i.e., in a shaver in the handle part, which is distant from the head of the shaver that is in contact with the hot water used to clean the blade(s) during shaving.

The apparatus may optionally also contain a heat reservoir unit that absorbs the heat of the hot water and preserves it for later use, when hot water may not be available. This heat reservoir is also connected to the hot side of the thermoelectric generator.

The thermoelectric generator produces an output voltage, induced by the temperature difference on opposite sides of the thermoelectric generator. That electrical power, which is the output voltage of the thermoelectric generator, is electrically connected to at least one of the following two electrical modules:

The first is a motor/vibrator that vibrates/rotates or performs any type of mechanical movement required for the appliance. This first module uses the power generated by the thermoelectric generator directly to perform the needed movement.

The second module is a rechargeable battery that is charged by the thermoelectric power and uses this power to drive the first module described above.

As mentioned above, the thermoelectric generator employs the Peltier principle operated in Seebeck effect. The hot side of the thermoelectric generator is connected to the portion of the shaver that comes into contact with the hot water during use. The cold side of the thermoelectric generator is connected to the handle. The heat conducting connections to and from the thermoelectric generator are preferably conventional heat pipes, although any other conventional thermal connector may be used. The appliance may optionally also contain a heat reservoir or heat sink to store excess heat for later use when the appliance is pulled out of the hot water. The heat generated by the hot water may be kept in the insulated heat reservoir when the hot water is not being applied. This heat reservoir is also connected to the hot side of the thermoelectric generator. If the temperature differential is caused by use of part of the appliance in a particularly cold environment, such that the hot side of the thermoelectric generator is at or around room temperature and the cold side is at a significantly lower temperature, the heat reservoir may be replaced or uses as a cold reservoir.

The power generated by the thermoelectric generator is fed via an electrical circuit to drive the motor of the appliance and/or to charge the rechargeable battery thereof.

Another aspect of the present invention is a method for driving small electrical appliances that may be operated in an environment with a temperature differential, such as where a wet environment differs in its temperature from a dry environment in which the appliance is used. The method includes the steps of thermally connecting one side of a thermoelectric generator to a heat source, such as hot water, and generating electrical power by means of the temperature differential caused by the heat of the hot water versus the relative cold of the dry environment of the handle. The method further includes the steps of connecting the electrical power generated by the thermoelectric generator to a vibrating/rotating device used in the appliance and/or for charging a rechargeable battery that, in turn, drives the vibrating/rotating device of the appliance. Preferably, the appliance is a vibrating electrical wet shaving device that includes a motor, and the thermoelectric generator is a Peltier cooler operating in the Seebeck mode to generate electrical power responsive to a temperature differential across the device. In a particularly preferred embodiment, the method includes the further step of thermally connecting the thermoelectric generator between the part of the shaver in contact with the hot water and the handle of the shaver, preferably by means of heat pipes. Moreover, in another particularly preferred embodiment, a heat reservoir is also used to enable continuous operation of the shaver, even when hot water is not being applied to the shaver.

### BRIEF DESCRIPTION OF THE DRAWING

Other features and advantages of the present invention will be more readily apparent upon reading the following description of currently preferred exemplified embodiments of the invention with reference to the accompanying drawing, in which:

FIG. 1 shows a diagrammatic view of a conventional wet electrical shaver—as is commercially available.

FIG. 2 shows a diagrammatic view of a preferred embodiment of the present invention.

FIG. 3 shows a schematic diagram of the electrical connections of an embodiment of the invention.

FIG. 4 shows an example of electronic circuit (10 from FIG. 3)

FIG. 5 shows an illustration of the power that can be achieved from temperature gradient with the Peltier cooler operating in the Seebeck mode

FIG. 6 shows a diagrammatic view of a conventional electrical toothbrush—as commercially available.

FIG. 7 shows a diagrammatic view of an embodiment of the present invention.

### DETAILED DESCRIPTION OF PREFERRED EMBODIMENTS

Throughout all the Figures, same or corresponding elements are generally indicated by same reference numerals. These depicted embodiments are to be understood as illustrative of the invention and not as limiting in any way. It should also be understood that the drawings are not necessarily to scale and that the embodiments are sometimes illustrated by graphic symbols, phantom lines, diagrammatic representations and fragmentary views. In certain instances, details which are not necessary for an understanding of the present invention or which render other details difficult to perceive may have been omitted.

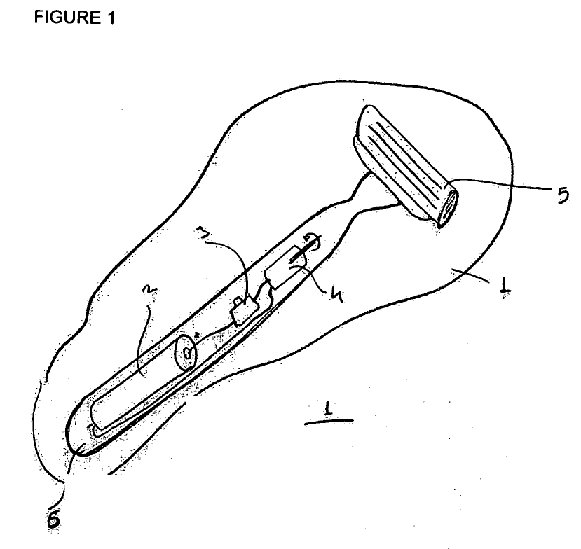

FIG. 1 shows a conventional electrical wet shaver in order to illustrate the problems solved by the present invention. The wet electrical shaver 1 includes a motor 4 that causes the shaving blade 5 to vibrate. In addition, shaver 1 contains a power source, in this case a battery 2, which is connected via a switch 3 to motor 4. Switching the shaver into the ON position causes the motor to rotate and results in vibration of the blade 5. The whole shaver, when in use, is held by its handle 6.

It is well known that, when shaving, the user rinses the blade from time to time under hot water. The temperature of the water is usually much higher than the temperature of the handle of the shaver. Conventional shavers use batteries as the power source to operate the vibration of the shaver.

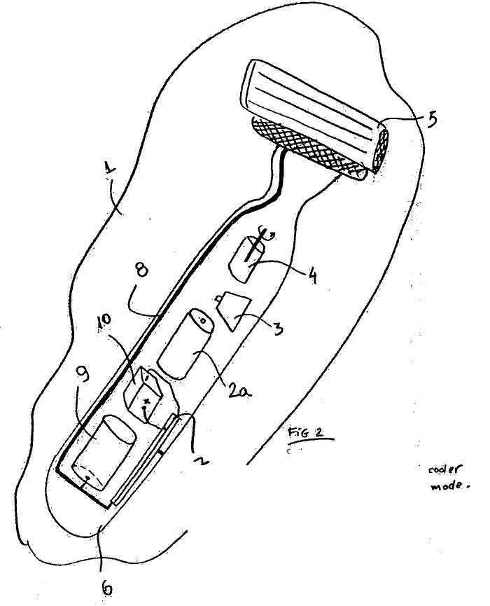

In FIGS. 2 and 3, illustrating the present invention, a thermoelectric generator 7 is positioned in the handle 6 of the shaver 1, preferably in proximity to the external envelope of the handle 6. Thus, one surface 12 of the thermoelectric generator 7 is kept at approximately room/user body temperature. The second surface 11 of the thermoelectric generator 7 is connected to the zone near the blade 5 by means of heat pipes 8. The temperature in this zone reaches significantly higher levels when rinsed under hot water.

Thermal contact of both sides of the thermoelectric generator 7 to the handle and to the blade zone, respectively, can be enhanced by means of thermal conducting paste or adhesives.

The embodiment described here also contains a heat reservoir module 9, connected to the blade zone 5—thus absorbing and storing the heat of the hot water. The heat reservoir 9 is connected to the blade zone 5 by means of heat pipes 8. Using such a heat reservoir enables the thermoelectric generator “hot” surface 11 to be kept at a relatively high temperature even when the shaver is not in contact with hot water (especially during regular shaving).

The output power of the thermoelectric generator 7 is used for directly driving motor 4 of the electrical shaver 1, as well as charging the rechargeable battery 2a. Such charging and motor driving may require an additional electrical circuit 10. Electrical circuit 10 accepts the low voltage generated by thermoelectric generator 7, and converts it to charging voltage for the battery, as well as to drive motor 4.

Motor 4 can be operated at a power on the order of several dozens of milliwatts, which magnitude of power can be generated by the thermoelectric generator 7.

In an alternative embodiment, the motor 4 is powered by the internal rechargeable battery 2a. The thermoelectric generator 7 may serve only to recharge the battery 2a, thereby extending its serviceable life without the necessity of an external recharger. In this embodiment, the thermoelectric generator 7 need not be directly connected to the motor 4.

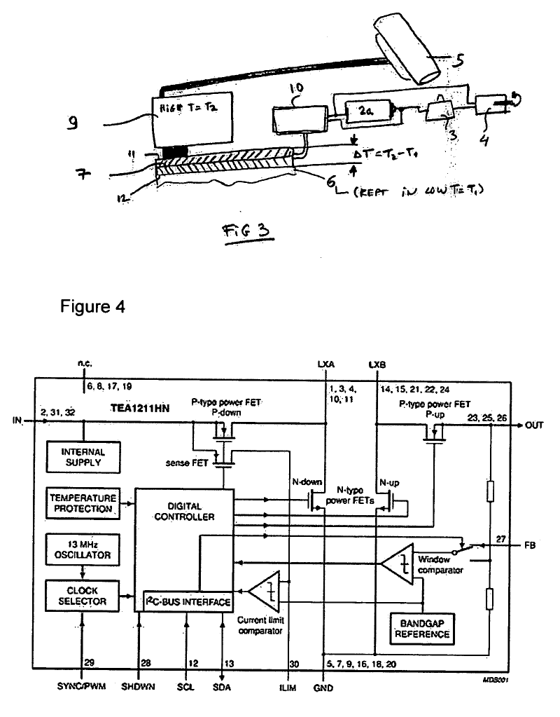

As schematically illustrated in FIG. 3, thermoelectric generator 7 is connected to the electric circuit 10 (example of such a circuit shown in FIG. 4) by a pair of wires, so that the voltage and current generated by thermoelectric generator 7 is conducted to the electric circuit 10 for power conversion. It is then further fed into the battery for recharging and into the motor 4 to drive it.

In operation, when shaver 1 is rinsed under hot water, the temperature of the blade zone 5 rises, and a temperature differential ΔT develops across thermoelectric generator 7 between the hot side 11 of the thermoelectric generator and the other side 12 attached to the handle of shaver 1. In addition, the heat energy is absorbed and kept in the heat reservoir. Applying that temperature differential to the thermoelectric generator causes generation of power: voltage and current, that is then fed through the electrical circuit 10 to the motor 4 and to the rechargeable battery 2a.

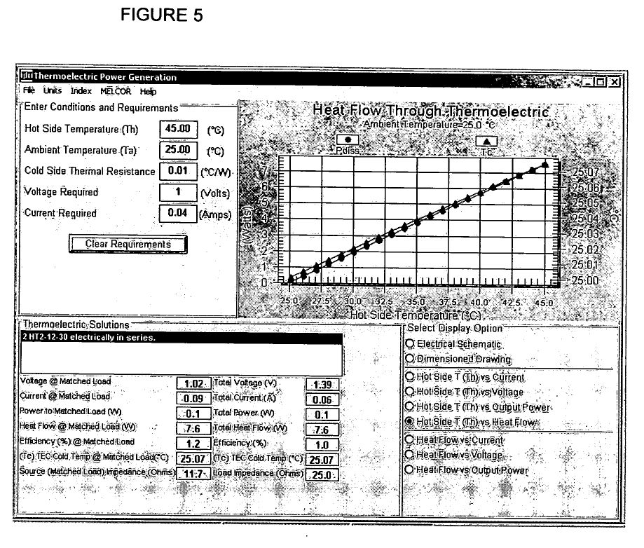

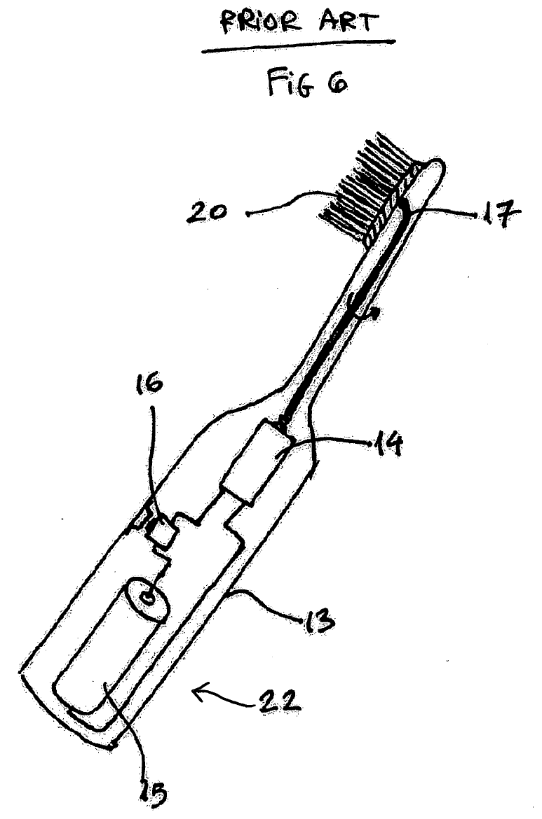

An example illustration of temperature difference with the Peltier cooler operating in the Seebeck mode generating voltage and current can be seen in FIG. 5

It should be appreciated that electrical energy generated by a thermoelectric generator may also be advantageously used for other purposes in addition to driving an electrical shaver as described. For example, the electrical energy may be used to drive an electrical toothbrush or other similar small appliances operated under hot water or otherwise under heated conditions, such as an electrical flossing device or sex toy.

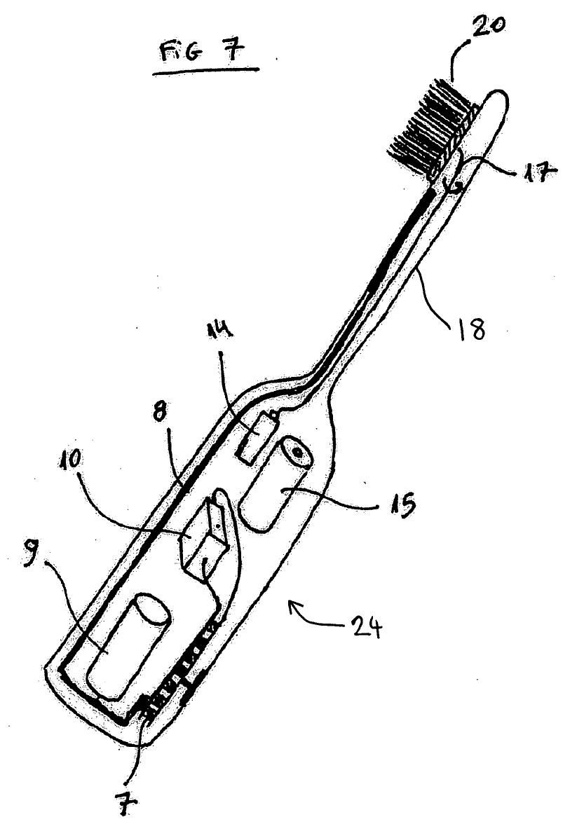

FIGS. 6 and 7 relate to the embodiment of the invention where the small electrical appliance is an electrical toothbrush.

FIG. 6 shows a conventional electrical toothbrush 22 in which a battery 15 (conventional or rechargeable) is connected to a motor 14 by means of a switch 16, and the motor 14 causes vibration or rotation of the brush 20 by means of a gear mechanism 17.

FIG. 7 shows an embodiment in which the thermoelectric generator 7 is used in an electrical toothbrush 24. The motor 14 and gear 17 connect to rotate and/or vibrate the brush 20. The thermoelectric generator 7 and heat reservoir apparatus 9, are used to power the toothbrush 24. The tasks and description of these parts of the appliance is similar to the same parts described above with respect to the electrical wet shaver (FIGS. 2 and 3).

While the preferred embodiments described herein operate by virtue of the temperature differential inherent in an operating environment involving the use of hot water, those of ordinary skill in the art will understand that the temperature differential driving the thermoelectric generator used in the appliance may be achieved by other means. However, in the present invention, the temperature differential is preferably present in the operating environment, rather than being artificially induced. Thus, the appliance need not be subjected to a source of heat or cold that is not already present in its operating environment. For example, if the appliance is a sex toy or dildo, the temperature differential may be caused by the heat of the body cavity in which it is used, versus the cold environment of the air-conditioned room. Other examples will be apparent to those of ordinary skill.

Although described above in connection with particular embodiments of the present invention, it should be understood the descriptions of the embodiments are illustrative of the invention and are not intended to be limiting. Various modifications and applications may occur to those skilled in the art without departing from the true spirit and scope of the invention as defined in the appended claims.

What is claimed as new and desired to be protected by Letters Patent is set forth in the appended claims and includes equivalents of the elements recited therein:

What is claimed is:

1. A small electrical appliance comprising a thermoelectrical generator that converts a heat differential, which is present in its environment of use, into electrical energy through a Peltier cooler operating in Seebeck effect.

2. An appliance according to claim 1, being an electric wet shaver.

3. An appliance according to claim 1, being an electric toothbrush.

4. An appliance according to claim 1, comprising a handle incorporating said thermoelectric generator, and an electric motor driving the appliance connected to the thermoelectric generator by an electrical circuit.

5. An appliance according to claim 4, further comprising a heat reservoir.

6. An appliance according to claim 5, comprising thermal connectors connecting the reservoir to a part receiving heat energy as hot water.

7. An appliance according to claim 6, further comprising a rechargeable battery.

8. A method for driving small electrical appliances that are operated in an environment with a temperature differential, comprising the steps of thermally connecting a thermoelectric generator to a heat source, and generating electrical power by the thermoelectric generator in response to heat supplied by the heat source.

9. A method according to claim 8, further including the steps of connecting the electrical power generated by the thermoelectric generator to a motor used for driving the appliance, and/or to a rechargeable battery.

10. A method in accordance with claim 8, wherein the heat source is hot water.

11. A method in accordance with claim 8, wherein the appliance is an electrical wet shaver.

12. A method in accordance with claim 8, wherein the appliance is an electrical toothbrush.
